(19) United States
(12) Patent Application Publication
(10) Pub. No.: US 2026/0136473 A1
(43) Pub. Date: May 14, 2026

(54) SUBSTRATE FOR PRINTED WIRING BOARD AND PRINTED WIRING BOARD

(71) Applicant: SUMITOMO ELECTRIC INDUSTRIES, LTD., Osaka (JP)

(72) Inventors: Takuto HIDANI, Osaka (JP); Kousuke MIURA, Osaka (JP); Katsunari MIKAGE, Osaka (JP); Koji NITTA, Osaka (JP); Yoshio OKA, Osaka (JP)

(73) Assignee: SUMITOMO ELECTRIC INDUSTRIES, LTD., Osaka (JP)

(21) Appl. No.: 18/695,641

(22) PCT Filed: Mar. 17, 2023
(86) PCT No.: PCT/JP2023/010645

§ 371 Date: Mar. 26, 2024

(30) Foreign Application Priority Data
Mar. 29, 2022 (JP) 2022-053406

(51) Int. Cl. H05K 3/18; H05K 1/02

(52) U.S. Cl. CPC H05K 3/181; H05K 1/0296; H05K 3/188; H05K 2203/1131

(57) ABSTRACT

A substrate for a printed wiring-board comprises: a base film having a main surface; a sintered material layer disposed on the main surface of the base film and formed of a plurality of sintered copper particles; and an electroless copper plating layer disposed on the sintered material layer. A palladium content in the sintered material layer is 0.1 atomic percent or less.

### TECHNICAL FIELD

The present disclosure relates to a substrate for a printed wiring board and a printed wiring board. This application claims priority based on Japanese Patent Application No. 2022-053406 filed on Mar. 29, 2022, the entire contents of which are incorporated herein by reference.

### BACKGROUND ART

For example, WO 2019/208077 (PTL 1) describes a substrate for a printed wiring board. The substrate for a printed wiring board described in PTL 1 includes a base film, a sintered material layer, and an electroless copper plating layer.

The base film has a main surface. The sintered material layer is disposed on the main surface of the base film. The sintered material layer is formed by sintering a plurality of copper particles. The electroless copper plating layer is disposed on the sintered material layer. The electroless copper plating layer is a copper layer formed by electroless plating.

A printed wiring board is formed using the substrate for a printed wiring board described in PTL 1. In this case, first, a resist pattern provided with an opening is disposed on the electroless copper plating layer, and electrolytic plating is performed on the electroless copper plating layer exposed at the opening, thereby forming an electrolytic copper plating layer on the electroless copper plating layer.

Second, the resist pattern is removed, and then the electroless copper plating layer and the sintered material layer exposed between the adjacent electrolytic copper plating layers are removed by etching. In this manner, by using the printed wiring board described in PTL 1, the printed wiring board having a wiring line including the sintered material layer, the electroless copper plating layer, and the electrolytic copper plating layer which are layered and disposed on the main surface of the base film is formed.

### CITATION LIST

### Patent Literature

PTL 1: WO 2019/208077

### SUMMARY OF INVENTION

A substrate for a printed wiring board according to the present disclosure includes a base film having a main surface, a sintered material layer disposed on the main surface of the base film and formed of a plurality of sintered copper particles, and an electroless copper plating layer disposed on the sintered material layer. A palladium content in the sintered material layer is 0.1 atomic percent or less.

### BRIEF DESCRIPTION OF DRAWINGS

FIG. 1 is a cross-sectional view of a substrate 100 for a printed wiring board.

FIG. 2 is a flowchart illustrating a method of manufacturing substrate 100 for a printed wiring board.

FIG. 3 is a cross-sectional view for illustrating a preparation step S1.

FIG. 4 is a cross-sectional view for illustrating a sintered material layer formation step S2.

FIG. 5 is a schematic configuration diagram of a plating apparatus 300 used in an electroless plating step S3.

FIG. 6 is a cross-sectional view for illustrating a first step S31.

FIG. 7 is a cross-sectional view for illustrating a second step S32.

FIG. 8 is a cross-sectional view of a printed wiring board 200.

FIG. 9 is a flowchart illustrating a method of manufacturing printed wiring board 200.

FIG. 10 is a cross-sectional view for illustrating a resist pattern formation step S4.

FIG. 11 is a cross-sectional view for illustrating an electrolytic plating step S5.

FIG. 12 is a cross-sectional view for illustrating a resist pattern removal step S6.

FIG. 13 is a plan view of a TEG for evaluation.

### DETAILED DESCRIPTION

### Problems to be Solved by Present Disclosure

In general, when an electroless copper plating layer is formed, palladium is applied as a catalyst onto a surface of a sintered material layer (a surface of the sintered material layer opposite to a main surface of a base film). In addition, when the electroless copper plating layer is formed, the base film on which the sintered material layer is formed is immersed in a plating solution. Since the sintered material layer is porous, the plating solution penetrates into the sintered material together with palladium.

As a result, in the substrate for a printed wiring board described in PTL 1, a palladium content in the sintered material layer increases. When the palladium content in the sintered material layer increases, it is necessary to remove palladium during etching, and thus it is difficult to form a wiring line on the main surface of the base film at a fine pitch.

The present disclosure has been made in view of the above-described problem of the conventional art. More specifically, the present disclosure provides a substrate for a printed wiring board with which a wiring line can be formed at a fine pitch.

### Advantageous Effect of the Present Disclosure

According to the substrate for a printed wiring board of the present disclosure, a wiring line can be formed at a fine pitch.

### Description of Embodiments

First, embodiments of the present disclosure will be listed and described.

(1) A substrate for a printed wiring board according to an embodiment include a base film having a main surface, a sintered material layer disposed on the main surface of the base film and formed of a plurality of sintered copper particles, and an electroless copper plating layer disposed on the sintered material layer. A palladium content in the sintered material layer is 0.1 atomic percent or less. According to the substrate for a printed wiring board of the above (1), a wiring line can be formed at a fine pitch.

(2) In the substrate for a printed wiring board according to the above (1), the palladium content in the sintered material layer may be 0.005 atomic percent or more. According to the substrate for a printed wiring board of the above (2), it is possible to ensure adhesion between the sintered material layer and the base film.

(3) In the substrate for a printed wiring board according to the above (1) or (2), a nickel content in the sintered material layer may be 0.5 atomic percent or less.

(4) In the substrate for a printed wiring board according to the above (3), the nickel content in the sintered material layer may be 0.03 atomic percent or more. According to the substrate for a printed wiring board of the above (4), it is possible to ensure the adhesion between the sintered material layer and the base film.

(5) In the substrate for a printed wiring board according to any one of the above (1) to (4), a palladium content in the electroless copper plating layer may be 0.1 atomic percent or less.

(6) In the substrate for a printed wiring board according to any one of the above (1) to (5), a palladium content in the base film at the main surface may be 0.01 atomic percent or less.

(7) A printed wiring board according to an embodiment includes a base film having a main surface, and a wiring line disposed on the main surface of the base film. The wiring line has a sintered material layer disposed on the main surface of the base film and formed of a plurality of sintered copper particles, an electroless copper plating layer disposed on the sintered material layer, and an electrolytic copper plating layer disposed on the electroless copper plating layer. A palladium content in the sintered material layer is 0.1 atomic percent or less. According to the printed wiring board of the above (7), the wiring line can be formed at a fine pitch.

(8) In the printed wiring board according to the above (7), the wiring line may have a plurality of wiring line portions extending in a second direction orthogonal to a first direction which is a normal direction of the main surface of the base film and arranged side by side in a third direction orthogonal to the first direction and the second direction. A distance between two adjacent wiring line portions of the plurality of wiring line portions may be 15 μm or less.

### Detailed Description of Embodiments

The details of embodiments of the present disclosure will be described with reference to the drawings. In the following drawings, the same or corresponding portions are designated by the same reference symbols and the same description thereof will not be repeated. A substrate for a printed wiring board and a printed wiring board according to the embodiment are referred to as a substrate 100 for a printed wiring board and a printed wiring board 200, respectively.

### (Configurations of Substrate 100 for Printed Wiring Board)

A configuration of substrate 100 for a printed wiring board will be described below.

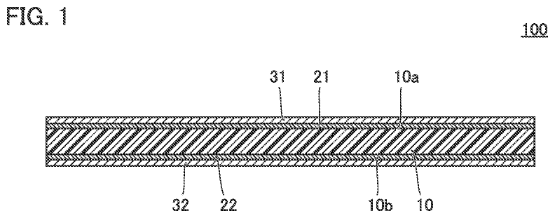

FIG. 1 is a cross-sectional view of substrate 100 for a printed wiring board. As shown in FIG. 1, substrate 100 for a printed wiring board includes a base film 10, a sintered material layer 21, and an electroless copper plating layer 31. Base film 10 may further include a sintered material layer 22 and an electroless copper plating layer 32.

Base film 10 has a first main surface 10a and a second main surface 10b. First main surface 10a and second main surface 10b are end surfaces of base film 10 in a thickness direction thereof. Second main surface 10b is a surface opposite to first main surface 10a. Base film 10 is formed of a flexible insulating material. Base film 10 is formed of, for example, polyimide, liquid crystal polymer, fluororesin, or the like. However, the material forming base film 10 is not limited to the material described above.

A palladium content in base film 10 at each of first main surface 10a and second main surface 10b may be 0.01 atomic percent or less. The palladium content in base film 10 at each of first main surface 10a and second main surface 10b is, for example, 0.001 atomic percent or more. A nickel content in base film 10 at each of first main surface 10a and second main surface 10b may be 0.05 atomic percent or less. The palladium content in base film 10 is measured on a cross section orthogonal to first main surface 10a and second main surface 10b using an energy dispersive X-ray spectrometer (SU8020, manufactured by Hitachi High-Technologies Corporation). An acceleration voltage for the measurement is set to 6 kV. The palladium content in base film 10 at first main surface 10a (second main surface 10b) is set as a palladium content in base film 10 at any region thereof within a distance of 100 nm from an interface between first main surface 10a and sintered material layer 21 (sintered material layer 22). The nickel content in base film 10 is also measured by the same method as the above.

Sintered material layer 21 is disposed on first main surface 10a. Sintered material layer 21 is formed of a plurality of sintered copper particles. Therefore, sintered material layer 21 is porous. An average particle size of the copper particles included in sintered material layer 21 may be 1 nm or more, or 30 nm or more. The average particle size of the copper particles included in sintered material layer 21 is 100 nm or less or 500 nm or less. That is, the copper particles included in sintered material layer 21 may be copper nanoparticles. The average particle size of the copper particles included in sintered material layer 21 is measured by a particle size distribution measuring apparatus (a microtrac particle size distribution analyzer UPA-150EX manufactured by Nikkiso Co., Ltd.).

A palladium content in sintered material layer 21 is 0.1 atomic percent or less. The palladium content in sintered material layer 21 is, for example, 0.005 atomic percent or more. By setting the palladium content in sintered material layer 21 to 0.005 atomic percent or more, adhesion to base film 10 can be ensured due to anchoring effect. The palladium content in sintered material layer 21 may be zero atomic percent. That is, sintered material layer 21 may not contain palladium. The palladium content in sintered material layer 21 is a palladium content at any region including entirety from an interface between base film 10 and sintered material layer 21 to an interface between sintered material layer 21 and electroless copper plating layer 31 in the thickness direction thereof. The palladium content in sintered material layer 21 is measured by the same method as the method for the palladium content in base film 10 except for the measurement region.

A nickel content in sintered material layer 21 is, for example, 0.5 atomic percent or less. The nickel content in sintered material layer 21 is, for example, 0.03 atomic percent or more. By setting the nickel content in sintered material layer 21 to 0.03 atomic percent or more, the adhesion to base film 10 can be ensured due to the anchoring effect. The nickel content in sintered material layer 21 is a nickel content at any region including entirety from the interface between base film 10 and sintered material layer 21 to the interface between sintered material layer 21 and electroless copper plating layer 31 in the thickness direction thereof. The nickel content in sintered material layer 21 is measured by the same method as the method for the palladium content in sintered material layer 21 except for the measurement region.

Sintered material layer 22 is disposed on second main surface 10b. Sintered material layer 22 is formed of a plurality of sintered copper particles. Therefore, sintered material layer 22 is porous. An average particle size of the copper particles included in sintered material layer 22 may be 1 nm or more, or 30 nm or more. The average particle size of the copper particles included in sintered material layer 22 may be 100 nm or less, or 500 nm or less. That is, the copper particles included in sintered material layer 22 may be copper nanoparticles. The average particle size of the copper particles included in sintered material layer 22 is measured by the same method as the method for the average particle size of the copper particles included in sintered material layer 21.

A palladium content in sintered material layer 22 is 0.1 atomic percent or less. The palladium content in sintered material layer 22 is, for example, 0.005 atomic percent or more. By setting the palladium content in sintered material layer 22 to 0.005 atomic percent or more, the adhesion to base film 10 can be ensured due to the anchoring effect. The palladium content in sintered material layer 22 may be zero atomic percent. That is, sintered material layer 22 may not contain palladium. The palladium content in sintered material layer 22 is a palladium content at any region including entirety from an interface between base film 10 and sintered material layer 22 to an interface between sintered material layer 22 and electroless copper plating layer 32 in the thickness direction thereof. The palladium content in sintered material layer 22 is measured by the same method as the method for the palladium content in sintered material layer 21 except for the measurement region.

A nickel content in sintered material layer 22 is, for example, 0.5 atomic percent or less. The nickel content in sintered material layer 22 is, for example, 0.03 atomic percent or more. By setting the nickel content in sintered material layer 22 to 0.03 atomic percent or more, the adhesion to base film 10 can be ensured due to the anchoring effect. The nickel content in sintered material layer 22 is a nickel content at any region including entirety from the interface between base film 10 and sintered material layer 22 to the interface between sintered material layer 22 and electroless copper plating layer 32 in the thickness direction thereof. The nickel content in sintered material layer 22 is measured by the same method as the method for the palladium content in sintered material layer 22 except for the measurement region.

Electroless copper plating layer 31 is disposed on sintered material layer 21. Electroless copper plating layer 31 is a copper layer formed by electroless plating. A palladium content in electroless copper plating layer 31 is 0.1 atomic percent or less. When electroless copper plating layer 31 is formed using palladium as a catalyst, electroless copper plating layer 31 having a palladium content of 0.1 atomic percent or less cannot be formed. The palladium content in electroless copper plating layer 31 is a palladium content at any region including entirety from the interface between sintered material layer 21 and electroless copper plating layer 31 to a surface of electroless copper plating layer 31 opposite to the interface in the thickness direction thereof. The palladium content in electroless copper plating layer 31 is measured by the same method as the method for the palladium content in base film 10 except for the measurement region.

A nickel content in electroless copper plating layer 31 is, for example, from 0.03 atomic percent to 0.5 atomic percent. Nickel is added to reduce internal stress acting on electroless copper plating layer 31. The nickel content in electroless copper plating layer 31 is a nickel content at any region including entirety from the interface between sintered material layer 21 and electroless copper plating layer 31 to the surface of electroless copper plating layer 31 opposite to the interface in the thickness direction thereof. The nickel content in electroless copper plating layer 31 is measured by the same method as the method for the palladium content in electroless copper plating layer 31 except for the measurement region.

Electroless copper plating layer 32 is disposed on sintered material layer 22. Electroless copper plating layer 32 is a copper layer formed by electroless plating. A palladium content in electroless copper plating layer 32 is 0.1 atomic percent or less. The palladium content in electroless copper plating layer 32 is a palladium content at any region including entirety from the interface between sintered material layer 22 and electroless copper plating layer 32 to the surface of electroless copper plating layer 32 opposite to the interface in the thickness direction thereof. The palladium content in electroless copper plating layer 32 is measured by the same method as the method for the palladium content in electroless copper plating layer 31 except for the measurement region.

A nickel content in electroless copper plating layer 32 is, for example, from 0.03 atomic percent to 0.5 atomic percent. The nickel content in electroless copper plating layer 32 is a nickel content at any region including entirety from the interface between sintered material layer 22 and electroless copper plating layer 32 to the surface of electroless copper plating layer 32 opposite to the interface in the thickness direction thereof. The nickel content in electroless copper plating layer 32 is measured by the same method as the method for the palladium content in electroless copper plating layer 32 except for the measurement region.

### Modification

In the above description, substrate 100 for a printed wiring board has sintered material layer 22 and electroless copper plating layer 32 in addition to sintered material layer 21 and electroless copper plating layer 31. However, substrate 100 for a printed wiring board may not have sintered material layer 22 or electroless copper plating layer 32.

### (Method of Manufacturing Substrate 100 for Printed Wiring Board)

Hereinafter, a method of manufacturing substrate 100 for a printed wiring board will be described.

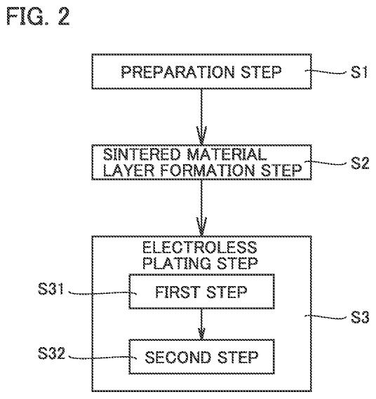

FIG. 2 is a flowchart illustrating a method of manufacturing substrate 100 for a printed wiring board. As shown in FIG. 2, the method of manufacturing substrate 100 for a printed wiring board includes a preparation step S1, a sintered material layer formation step S2, and an electroless plating step S3. Sintered material layer formation step S2 is performed after preparation step S1. Electroless plating step S3 is performed after sintered material layer formation step S2.

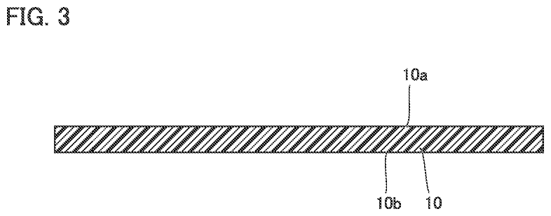

FIG. 3 is a cross-sectional view for illustrating preparation step S1. In preparation step S1, as shown in FIG. 3, base film 10 is prepared. In base film 10 prepared in preparation step S1, sintered material layer 21 and electroless copper plating layer 31 are not disposed on first main surface 10a, and sintered material layer 22 and electroless copper plating layer 32 are not disposed on second main surface 10b.

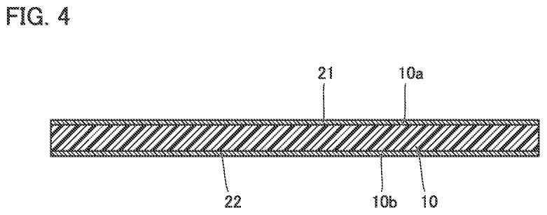

FIG. 4 is a cross-sectional view for illustrating sintered material layer formation step S2. In sintered material layer formation step S2, as shown in FIG. 4, sintered material layer 21 and sintered material layer 22 are formed on first main surface 10a and second main surface 10b, respectively. In sintered material layer formation step S2, first, a paste including copper particles is applied onto first main surface 10a and second main surface 10b. Second, a solvent contained in the applied paste is dried. Third, the dried paste is fired. As a result, the copper particles included in the dried paste are sintered to one another, and sintered material layer 21 and sintered material layer 22 are formed.

Although not shown in the figure, after sintered material layer formation step S2 is performed and before electroless plating step S3 is performed, a degreasing treatment and an acid cleaning treatment are performed on a surface of sintered material layer 21 (i.e., a surface of sintered material layer 21 opposite to first main surface 10a) and a surface of sintered material layer 22 (i.e., a surface of sintered material layer 22 opposite to second main surface 10b).

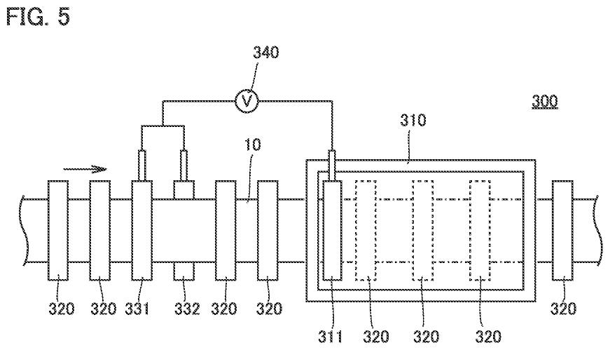

Electroless plating step S3 is performed using a plating apparatus 300. FIG. 5 is a schematic configuration diagram of plating apparatus 300 used in electroless plating step S3. As shown in FIG. 5, plating apparatus 300 includes a plating treatment tank 310, a plurality of rollers 320, an electrode roller 331, an electrode roller 332, and a power supply 340.

A plating solution is stored in plating treatment tank 310. The plating solution contains copper. The plating solution may contain nickel. An electrode 311 is disposed inside plating treatment tank 310. Electrode 311 is formed of a conductive material. Electrode 311 is formed of, for example, titanium. Electrode 311 is immersed in the plating solution.

The plurality of rollers 320 are arranged side by side in a conveyance direction of base film 10 (see the arrow in FIG. 5). Base film 10 is conveyed in the conveyance direction by rotating the plurality of rollers 320. Base film 10 passes through the plating solution stored in plating treatment tank 310 during the conveyance.

Electrode roller 331 and electrode roller 332 are positioned to contact base film 10 before passing through the plating solution. Electrode roller 331 and electrode roller 332 are in contact with sintered material layer 21 and sintered material layer 22, respectively. Electrode roller 331 and electrode roller 332 are formed of, for example, stainless steel.

Power supply 340 is electrically connected to electrode 311, electrode roller 331, and electrode roller 332. More specifically, the positive electrode of power supply 340 is electrically connected to electrode 311, and the negative electrode of power supply 340 is electrically connected to electrode roller 331 and electrode roller 332.

Plating apparatus 300 may be used for manufacturing a substrate for a printed wiring board other than substrate 100 for a printed wiring board. When manufacturing the substrate for a printed wiring board other than substrate 100 for a printed wiring board, a pre-dip step of applying a palladium catalyst to the surface of sintered material layer 21 and the surface of sintered material layer 22, an activator step, and a reduction step are performed before an electroless plating step is performed. Therefore, palladium may be attached to roller 320, and a small amount of palladium may be mixed into electroless copper plating layer 31 and electroless copper plating layer 32 during electroless plating step S3.

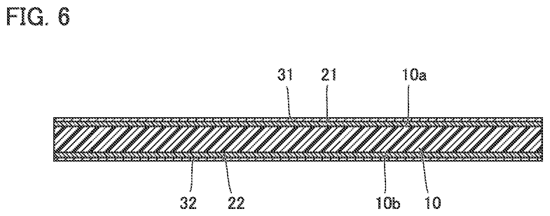

Electroless plating step S3 includes a first step S31 and a second step S32 performed after first step S31. In first step S31, current is applied between electrode 311 and electrode roller 331 and between electrode 311 and electrode roller 332 by power supply 340. FIG. 6 is a cross-sectional view for illustrating first step S31. As shown in FIG. 6, electroless copper plating layer 31 and electroless copper plating layer 32 are rapidly formed on the surface of sintered material layer 21 and the surface of sintered material layer 22, respectively, by electrical energy due to the current application. Electroless copper plating layer 31 and electroless copper plating layer 32 formed in the above step suppress penetration of the plating solution into sintered material layer 21 and sintered material layer 22.

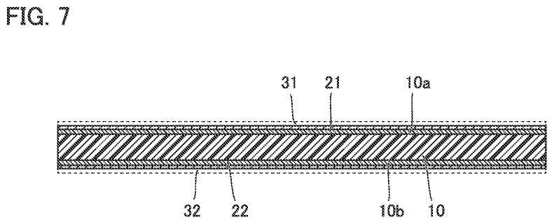

FIG. 7 is a cross-sectional view for illustrating second step S32. In second step S32, the current application between electrode 311 and electrode roller 331 and between electrode 311 and electrode roller 332 is stopped. However, since electroless copper plating layer 31 and electroless copper plating layer 32 are formed in first step S31, as shown in FIG. 7, the growth of electroless copper plating layer 31 and electroless copper plating layer 32 continues due to a self-catalytic action of copper without using the palladium catalyst. Through the above steps, substrate 100 for a printed wiring board having the structure shown in FIG. 1 is formed.

One of the reasons why a trace amount of palladium may be contained in sintered material layer 21, sintered material layer 22, electroless copper plating layer 31, electroless copper plating layer 32, and base film 10 is that a trace amount of palladium may be present in a manufacturing apparatus or the like. In the substrate for a printed wiring board of the present disclosure, even when palladium is present due to any circumstances, palladium in sintered material layer 21 and sintered material layer 22 is reduced to 0.1 atomic percent or less, thereby enabling the wiring line to be formed at a fine pitch.

### (Configuration of Printed Wiring Board 200)

A configurations of printed wiring board 200 will be described below.

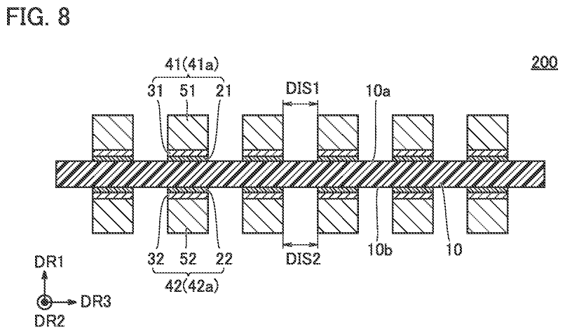

FIG. 8 is a cross-sectional view of printed wiring board 200. As shown in FIG. 8, printed wiring board 200 includes base film 10 and a wiring line 41. Printed wiring board 200 may further include a wiring line 42.

A normal direction of first main surface 10a (second main surface 10b) is defined as a first direction DR1. A direction orthogonal to first direction DR1 is defined as a second direction DR2. A direction orthogonal to first direction DR1 and second direction DR2 is defined as a third direction DR3.

Wiring line 41 is disposed on first main surface 10a. Wiring line 41 includes sintered material layer 21 disposed on first main surface 10a, electroless copper plating layer 31 disposed on sintered material layer 21, and an electrolytic copper plating layer 51 disposed on electroless copper plating layer 31. Electrolytic copper plating layer 51 is a copper layer formed by electrolytic plating.

Wiring line 42 is disposed on second main surface 10b. Wiring line 42 includes sintered material layer 22 disposed on second main surface 10b, electroless copper plating layer 32 disposed on sintered material layer 22, and an electrolytic copper plating layer 52 disposed on electroless copper plating layer 32. Electrolytic copper plating layer 52 is a copper layer formed by electrolytic plating.

Although not shown in the figure, wiring line 41 and wiring line 42 are electrically connected to each other by a conductor layer disposed at an inner wall surface of a through hole (or embedded in the through hole) that extend through base film 10 in the thickness direction.

Wiring line 41 includes a plurality of wiring line portions 41a. Wiring line portions 41a extend in second direction DR2. The plurality of wiring line portions 41a are arranged side by side in third direction DR3. A distance between two adjacent wiring line portions 41a of the plurality of wiring line portions 41a in third direction DR3 is referred to as a distance DIS1. Distance DIS1 may be 15 μm or less. Distance DIS1 may be 10 μm or less, or may be 20 μm or less.

Wiring line 42 includes a plurality of wiring line portions 42a. Wiring line portions 42a extend in second direction DR2. The plurality of wiring line portions 42a are arranged side by side in third direction DR3. A distance between two adjacent wiring line portions 42a of the plurality of wiring line portions 42a in third direction DR3 is referred to as a distance DIS2. Distance DIS2 may be 15 μm or less. Distance DIS2 may be 10 μm or less, or may be 20 μm or less.

### Modification

In the above description, printed wiring board 200 includes wiring line 42 in addition to wiring line 41. However, printed wiring board 200 may not have wiring line 42.

### (Method of Manufacturing Printed Wiring Board 200)

Hereinafter, a method of manufacturing printed wiring board 200 will be described.

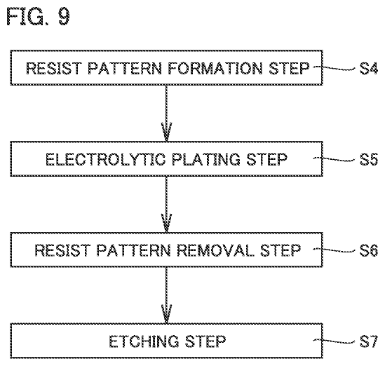

FIG. 9 is a flowchart illustrating a method of manufacturing printed wiring board 200. As shown in FIG. 9, the method of manufacturing printed wiring board 200 includes a resist pattern formation step S4, an electrolytic plating step S5, a resist pattern removal step S6, and an etching step S7.

Electrolytic plating step S5 is performed after resist pattern formation step S4. Resist pattern removal step S6 is performed after electrolytic plating step S5. Etching step S7 is performed after resist pattern removal step S6. Printed wiring board 200 is formed using substrate 100 for a printed wiring board.

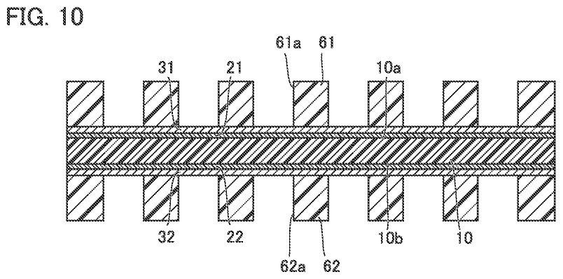

FIG. 10 is a cross-sectional view for illustrating resist pattern formation step S4. In resist pattern formation step S4, as shown in FIG. 10, a resist pattern 61 and a resist pattern 62 are formed on electroless copper plating layer 31 and electroless copper plating layer 32, respectively.

Resist pattern 61 is provided with an opening 61a. Opening 61a extends through resist pattern 61 in a thickness direction. Electroless copper plating layer 31 is exposed at opening 61a. Resist pattern 62 is provided with an opening 62a. Opening 62a extends through resist pattern 62 in the thickness direction. Electroless copper plating layer 32 is exposed at opening 62a.

In resist pattern formation step S4, first, a dry film resist is applied onto electroless copper plating layer 31 and electroless copper plating layer 32. Second, the applied dry film resist is exposed and developed. As a result, the remaining portion of the dry film resist that is not removed serves as resist pattern 61 and resist pattern 62, and the portion where the dry film resist is removed serves as opening 61a and opening 62a.

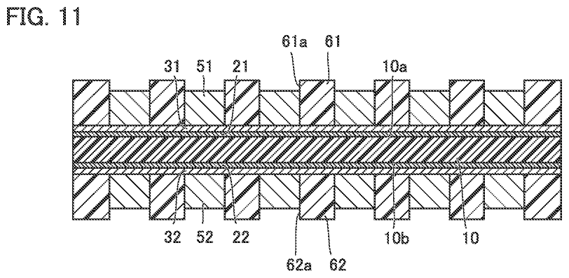

FIG. 11 is a cross-sectional view for illustrating electrolytic plating step S5. In electrolytic plating step S5, as shown in FIG. 11, electrolytic copper plating layer 51 is formed on electroless copper plating layer 31 exposed at opening 61a, and electrolytic copper plating layer 52 is formed on electroless copper plating layer 32 exposed at opening 62a.

Electrolytic copper plating layer 51 and electrolytic copper plating layer 52 are formed by applying current to electroless copper plating layer 31 and electroless copper plating layer 32 in a plating solution containing copper to perform electrolytic plating on electroless copper plating layer 31 exposed at opening 61a and electroless copper plating layer 32 exposed at opening 62a, respectively.

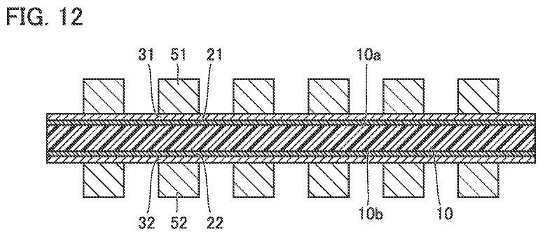

FIG. 12 is a cross-sectional view for explaining resist pattern removal step S6. In resist pattern removal step S6, as shown in FIG. 12, resist pattern 61 on electroless copper plating layer 31 is removed, and resist pattern 62 on electroless copper plating layer 32 is removed. As a result, electroless copper plating layer 31 and sintered material layer 21 are exposed between the two adjacent electrolytic copper plating layers 51, and electroless copper plating layer 32 and sintered material layer 22 are exposed between the two adjacent electrolytic copper plating layers 52.

In etching step S7, the portions of electroless copper plating layer 31 and sintered material layer 21 exposed between the two adjacent electrolytic copper plating layers 51 and the portions of electroless copper plating layer 32 and sintered material layer 22 exposed between the two adjacent electrolytic copper plating layers 52 are removed by etching. Through the above steps, printed wiring board 200 having the structure shown in FIG. 7 is formed.

### (Effects of Substrate 100 for Printed Wiring Board and Printed Wiring Board 200)

Hereinafter, the effect of substrate 100 for a printed wiring board will be described.

Substrate 100 for a printed wiring board eliminates a need to apply the palladium catalyst to the surfaces of sintered material layer 21 and sintered material layer 22 in order to form electroless copper plating layer 31 and electroless copper plating layer 32. Therefore, according to substrate 100 for a printed wiring board, the pre-dip step for applying the palladium catalyst, the activator step, and the reduction step can be omitted in the manufacturing process, and thus the manufacturing process can be simplified.

Hereinafter, the effect of printed wiring board 200 will be described below. In the process of manufacturing substrate 100 for a printed wiring board, electroless copper plating layer 31 and electroless copper plating layer 32 are rapidly formed on sintered material layer 21 and sintered material layer 22, respectively, without using the palladium catalyst by applying current between electrode 311 and electrode roller 331 and between electrode 311 and electrode roller 332 during an initial stage of electroless plating step S3. As a result, the penetration of the plating solution into sintered material layer 21 and sintered material layer 22 is suppressed. Therefore, in substrate 100 for a printed wiring board, the contents of palladium and nickel in each of sintered material layer 21 and sintered material layer 22 are low.

In a case where the content of palladium or nickel in each of sintered material layer 21 and sintered material layer 22 is high, in etching step S7, palladium or nickel in electroless copper plating layer 31 and sintered material layer 21 exposed between two adjacent electrolytic copper plating layers 51 and palladium or nickel in electroless copper plating layer 32 and sintered material layer 22 exposed between two adjacent electrolytic copper plating layers 52 need to be removed.

In this case, since an undercut may occur in wiring line 41 and wiring line 42, when the content of palladium or nickel in each of sintered material layer 21 and sintered material layer 22 is high, it is difficult to form wiring line 41 and wiring line 42 at a fine pitch.

However, since printed wiring board 200 is formed using substrate 100 for a printed wiring board in which the contents of palladium and nickel in each of sintered material layer 21 and sintered material layer 22 are low, the undercut of wiring line 41 and wiring line 42 is unlikely to occur when etching step S7 is performed, and thus wiring line 41 and wiring line 42 can be formed at a fine pitch. The undercut of wiring line 41 refers to a notch formed between electroless copper plating layer 31 and electrolytic copper plating layer 51 on a side surface of wiring line 41. Similarly, the undercut of wiring line 42 refers to a notch formed between electroless copper plating layer 32 and electrolytic copper plating layer 52 on a side surface of wiring line 42.

### Example

Using sample 1 to sample 5, an influence of the palladium content in sintered material layer 21 on a fine pitch of wiring line 41 was evaluated. The palladium content in sintered material layer 21 was changed for sample 1 to sample 5. In sample 1, sample 3, and sample 4, electroless copper plating layer 31 was formed using first step S31 and second step S32. In sample 1, the concentration of nickel in a plating solution used for forming electroless copper plating layer 31 was set higher than those in sample 3 and sample 4. In sample 2 and sample 5, electroless copper plating layer 31 was formed by electroless plating using a palladium catalyst. In sample 2, the concentration of nickel in the plating solution used for forming electroless copper plating layer 31 was higher than that in sample 5.

In sample 1 to sample 5, the palladium content in electroless copper plating layer 31, the nickel content in sintered material layer 21, and the palladium content in base film 10 at first main surface 10a were also changed.

TABLE 1

| | Sam- | Sam- | Sam- | Sam- | Sam- |
|---|---|---|---|---|---|
| | ple 1 | ple 2 | ple 3 | ple 4 | ple 5 |
| Pd Content in Electroless | 0.05 | 0.5 | 0.03 | 0.07 | 0.6 |
| Copper Plating Layer 31 | | | | | |
| (atomic %) | | | | | |
| Pd Content in Sintered | 0.02 | 0.11 | 0.01 | 0.08 | 0.14 |
| Material Layer 21 | | | | | |
| (atomic %) | | | | | |
| Ni Content in Sintered | 0.8 | 1.5 | 0.09 | 0.35 | 0.45 |
| Material Layer 21 | | | | | |
| (atomic %) | | | | | |
| Pd Content in Base Film 10 | 0.004 | 0.019 | 0.002 | 0.008 | 0.023 |
| at First Main Surface 10a | | | | | |
| (atomic %) | | | | | |
| Fine Pitch of Wiring Line 41 | B | D | A | A | C |
| Rectangularity of Wiring | D | D | A | B | D |
| Line 41 | | | | | |

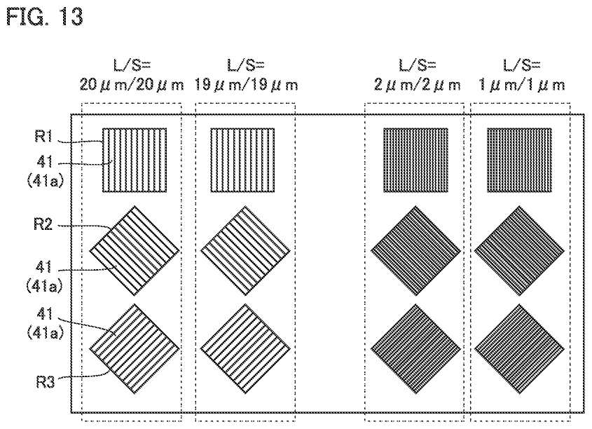

For the evaluation of the fine pitch of the wiring line, a test element group (TEG) for evaluation was used. FIG. 13 is a plan view of the TEG for evaluation. As shown in FIG. 13, the TEG for evaluation includes base film 10 and wiring line 41. In the TEG for evaluation, first main surface 10a has 20 wiring line formation regions R1, 20 wiring line formation regions R2, and 20 wiring line formation regions R3. In a left-right direction, 20 wiring line formation regions R1, 20 wiring line formation regions R2, and 20 wiring line formation regions R3 are arranged in rows.

Wiring line 41 having a plurality of wiring line portions 41a is formed on wiring line formation region R1, wiring line formation region R2, and wiring line formation region R3. Wiring line portions 41a formed on wiring line formation region R1 extend in an up-and-down direction. Wiring line portions 41a formed on wiring line formation region R2 and wiring line portions 41a formed on wiring line formation region R3 extend in directions inclined by 45° and −45° relative to the up-and-down direction, respectively.

Wiring line portions 41a formed on the n-th (n is a natural number of 20 or less) wiring line formation region R1 from the right among 20 wiring line formation region R1 have an L/S value of n μm/n μm. L is a width of wiring line portions 41a, and S is distance DIS1. L/S values for wiring line portions 41a formed on wiring line formation region R2 and wiring line portions 41a formed on wiring line formation region R3 were changed as well. An aspect ratio of wiring line portions 41a (a value obtained by dividing a height of wiring line portions 41a by a width of wiring line portions 41a) was set to be from 1 to 2.

Wiring line 41 was observed using a scanning electron microscope (SEM) for each of 20 wiring line formation regions R1, each of 20 wiring line formation regions R2, and each of 20 wiring line formation regions R3 to determine whether or not the wiring line formation was properly performed.

When minimum values of the width and distance DIS1 at which wiring line portions 41a were able to be properly formed were 10 μm or less, the evaluation was determined as A. When minimum values of the width and distance DIS1 at which wiring line portions 41a were able to be properly formed were more than 10 μm and 20 μm or less, the evaluation was determined as B. When minimum values of the width and distance DIS1 at which wiring line portions 41a were able to be properly formed were more than 20 μm and 30 μm or less, the evaluation was determined as C. When minimum values of the width and distance DIS1 at which wiring line portions 41a were able to be properly formed were more than 30 μm, the evaluation was determined as D.

As shown in Table 1, when the palladium content in sintered material layer 21 was 0.1 atomic percent or less, the evaluation of the fine pitch was B or higher. On the other hand, when the palladium content in sintered material layer 21 was more than 0.1 atomic percent, the evaluation of the fine pitch was C or lower. From this comparison, it was found that wiring line 41 can be formed at a fine pitch by setting the palladium content in sintered material layer 21 to 0.1 atomic percent or less. In the samples in which the palladium content in sintered material layer 21 was 0.1 atomic percent or less, the palladium content in electroless copper plating layer 31 and the palladium content in base film 10 at first main surface 10a were 0.1 atomic percent or less and 0.01 atomic percent or less, respectively.

Rectangularity of wiring line 41 was also evaluated for sample 1 to sample 5. For the evaluation of the rectangularity of wiring line 41, first, a cross-sectional image of wiring line 41 was obtained using a SEM. The SEM is, for example, ULTRA55 manufactured by Carl Zeiss Co., Ltd., and the measurement was performed under a condition of an acceleration voltage of 3 kV, an aperture of 30 μm, a WD of 5 mm, and an inclination of 0°. The cross-sectional image was obtained in a cross section orthogonal to an extending direction of wiring line 41. Prior to the observation of the cross section, each sample was prepared by epoxy resin embedding, form polishing, cross-section polishing with a cross polisher (at an acceleration voltage of 6 kV for 4 hours), and carbon deposition (2 nm).

A width of wiring line 41 on an upper surface and a width of wiring line 41 on a lower surface are referred to as a first width and a second width, respectively. When a value obtained by dividing the first width by the second width was 0.9 or more, the rectangularity of wiring line 41 was evaluated as A. When the value obtained by dividing the first width by the second width was 0.8 or more and less than 0.9, the rectangularity of wiring line 41 was evaluated as B. When the value obtained by dividing the first width by the second width was 0.7 or more and less than 0.8, the rectangularity of wiring line 41 was evaluated as C. When the value obtained by dividing the first width by the second width was less than 0.7, the rectangularity of wiring line 41 was evaluated as D.

For sample 3 and sample 4, the rectangularity of wiring line 41 was evaluated as B or higher. On the other hand, for sample 1, the rectangularity of wiring line 41 was evaluated as D. In addition, sample 3 and sample 4 had a nickel content of 0.5 atomic percent or less in sintered material layer 21. On the other hand, sample 1 had a nickel content of more than 0.5 atomic percent in sintered material layer 21. From this comparison, it was found that the rectangularity of wiring line 41 was improved by setting the content of nickel in sintered material layer 21 to 0.5 atomic percent or less in addition to setting the palladium content in sintered material layer 21 to 0.1 atomic percent or less.

It should be understood that the embodiments disclosed herein are illustrative and non-restrictive in every respect. The scope of the present invention is defined by the terms of the claims rather than the embodiments described above, and is intended to include any modifications within the scope and meaning equivalent to the terms of the claims.

### REFERENCE SIGNS LIST

10 base film; 10a first main surface; 10b second main surface; 21 sintered material layer; 22 sintered material layer; 31 electroless copper plating layer; 32 electroless copper plating layer; 41 wiring line; 41a wiring line portion; 42 wiring line; 42a wiring line portion; 51, 52 electrolytic copper plating layer; 61 resist pattern; 61a opening; 62 resist pattern; 62a opening; 100 substrate for a printed wiring board; 200 printed wiring board; 300 plating apparatus; 310 plating treatment tank; 311 electrode; 320 roller, 331, 332 electrode roller; 340 power supply; DIS1 distance; DIS2 distance; DR1 first direction; DR2 second direction; DR3 third direction; S1 preparation step; S2 sintered material layer formation step; S3 electroless plating step; S4 resist pattern formation step; S5 electrolytic plating step; S6 resist pattern removal step; S7 etching step; S31 first step; S32 second step.

1. A substrate for a printed wiring board, the substrate comprising:
a base film having a main surface;
a sintered material layer disposed on the main surface and formed of a plurality of sintered copper particles; and
an electroless copper plating layer disposed on the sintered material layer,
wherein a palladium content in the sintered material layer is 0.1 atomic percent or less.

2. The substrate for a printed wiring board according to claim 1, wherein the palladium content in the sintered material layer is 0.005 atomic percent or more.

3. The substrate for a printed wiring board according to claim 1, wherein a nickel content in the sintered material layer is 0.5 atomic percent or less.

4. The substrate for a printed wiring board according to claim 3, wherein the nickel content in the sintered material layer is 0.03 atomic percent or more.

5. The substrate for a printed wiring board according to claim 1, wherein a palladium content in the electroless copper plating layer is 0.1 atomic percent or less.

6. The substrate for a printed wiring board according to claim 1, wherein a palladium content in the base film at the main surface is 0.01 atomic percent or less.

7. A printed wiring board comprising:
a base film having a main surface; and
a wiring line disposed on the main surface,
wherein the wiring line has a sintered material layer disposed on the main surface and formed of a plurality of sintered copper particles, an electroless copper plating layer disposed on the sintered material layer, and an electrolytic copper plating layer disposed on the electroless copper plating layer, and
a palladium content in the sintered material layer is 0.1 atomic percent or less.

8. The printed wiring board according to claim 7,
wherein the wiring line has a plurality of wiring line portions extending along a second direction orthogonal to a first direction which is a normal direction of the main surface and arranged side by side in a third direction orthogonal to the first direction and the second direction, and
a distance between two adjacent wiring line portions of the plurality of wiring line portions is 15 μm or less.
